(19) United States
(12) Patent Application Publication
(10) Pub. No.: US 2013/0122278 A1
(43) Pub. Date: May 16, 2013

(54) POLYCRYSTALLINE SILICON INGOT MANUFACTURING APPARATUS, POLYCRYSTALLINE SILICON INGOT MANUFACTURING METHOD, AND POLYCRYSTALLINE SILICON INGOT

(71) Applicants: Koji Tsuzukihashi, Akita-shi (JP); Saburo Wakita, Noda-shi (JP); Hiroshi Ikeda, Tokyo (JP); Masahiro Kanai, Akita-shi (JP)

(72) Inventors: Koji Tsuzukihashi, Akita-shi (JP); Saburo Wakita, Noda-shi (JP); Hiroshi Ikeda, Tokyo (JP); Masahiro Kanai, Akita-shi (JP)

(73) Assignees: MITSUBISHI MATERIALS ELECTRONIC CHEMICALS CO LTD, AKITA (JP); MITSUBISHI MATERIALS CORPORATION, TOKYO (JP)

(21) Appl. No.: 13/811,119

(22) PCT Filed: Jul. 21, 2011
(86) PCT No.: PCT/JP2011/066546

§ 371 Date: Jan. 18, 2013

(30) Foreign Application Priority Data
Jul. 22, 2010 (JP) 2010-164774

(51) Int. Cl. C30B 30/00

(52) U.S. Cl. CPC C30B 30/00
USPC 428/220; 423/348; 65/355; 65/33.9

(57) ABSTRACT

A polycrystalline silicon ingot manufacturing apparatus, a polycrystalline silicon ingot manufacturing method, and a polycrystalline silicon ingot are provided. The apparatus comprises: a crucible having a rectangular shape in a cross-section; an upper heater provided above the crucible; and a lower heater provided below the crucible. A silicon melt stored in the crucible is solidified from a bottom surface of the crucible upward unidirectionally. The apparatus further comprises an auxiliary heater that heats at least a bottom-surface-side portion of a sidewall of the crucible. The production yield can be improved by using the apparatus and by reducing the oxygen concentration at the location where the oxygen concentration tends to be high locally at the bottom part of the ingot.

### CROSS-REFERENCE TO RELATED PATENT APPLICATIONS

This application is a U.S. National Phase Application under 35 U.S.C. §371 of International Patent Application No. PCT/JP2011/066546, filed Jan. 26, 2012, and claims the benefit of Japanese Patent Application No. 2010-164774, filed Jul. 22, 2010, all of which are incorporated by reference herein. The International Application was published in Japanese on Jan. 26, 2012 as International Publication No. WO/2012/011523 under PCT Article 21(2).

### FIELD OF THE INVENTION

The present invention relates to a polycrystalline silicon ingot manufacturing apparatus, a polycrystalline silicon ingot manufacturing method, a polycrystalline silicon ingot, in which a silicon melt stored in the crucible is solidified from a bottom surface of the crucible upward unidirectionally.

### BACKGROUND OF THE INVENTION

### Related Art Document

In order to manufacture a polycrystalline silicon wafer, first a polycrystalline silicon ingot is sliced in a predetermined thickness to produce a polycrystalline silicon slice as described in Patent Literature 1, for example. Then, the polycrystalline silicon slice is cut off in a predetermined size to manufacture the polycrystalline silicon wafer. The polycrystalline silicon wafer is utilized for a base material of solar cells mainly. The property of the polycrystalline ingot, which is the base material of the solar cells, has a significant impact on the conversion efficiency or the like in the solar cells.

Particularly, the conversion efficiency of the solar cells is significantly reduced when the polycrystalline silicon includes a larger amount of oxygen or other impurities. Therefore, it is necessary to reduce the amount of oxygen and other impurities in the polycrystalline silicon used for the base material of the solar cells.

The amount of oxygen and other impurities tend to be high at the bottom and the top part of the polycrystalline silicon ingot when the polycrystalline silicon ingot is manufactured by solidifying the silicon melt stored in a crucible unidirectionally. The bottom part and the top part are the solidification-starting point and the solidification-end point, respectively. Here, solidifying the silicon melt unidirectionally means the silicon melt is solidified in a specific direction sequentially. Because of this, the bottom and top parts of the ingot are cut off to use the remaining part as the materials for polycrystalline silicon wafer in order to reduce the amount of oxygen and other impurities.

The reasons for the high amount of oxygen and other impurities at the bottom and top parts of the polycrystalline silicon ingot are explained below.

When the silicon melt stored in the crucible is solidified upward unidirectionally, impurities are discharged from the solid-phase to the liquid phase. Therefore, the amount of impurities is reduced in the solid phase. However, in the top part of the polycrystalline silicon ingot, which is solidification-end point, the amount of the impurities is increased significantly.

In addition, oxygen contaminates into the silicon melt from silica (SiO₂), when the silicon melt is stored in a crucible made of silica. The oxygen in the silicon melt is released from the liquid level as SiO gas. In the beginning of the solidification, oxygen contaminates from the bottom surface and side surface of the crucible. Therefore, the amount of oxygen in the silicon melt is high at the beginning of the solidification. When solidification proceeds and the solid-liquid interface moves upward, oxygen contaminates only from the side surface of the crucible. Therefore, the amount of oxygen in the ingot is reduced gradually and leveled off to a constant value. Because of this, the amount of oxygen is high at the bottom part that is the solidification-start point.

The polycrystalline silicon ingot described above is manufactured using an unidirectionally solidifying method with the molding devices described in Patent Literatures 2 and 3, for example.

In the molding device described in Patent Literature 2, an upper heater is provided above the crucible, and a lower heater is provided below the crucible, A silicon melt is produced by melting silicon raw materials in the crucible by heating with the upper and lower heaters. Then, the silicon melt stored in the crucible is solidified upward unidirectionally from the bottom surface of the crucible by turning of the lower heater, dissipating heat from the bottom portion of the crucible.

The molding device described in Patent Literature 3 has a side heater facing the side surface of the crucible. In the device, the silicon melt is produced by melting the silicon raw materials in the crucible by heating with the side heater of the crucible. Then, the crucible is lowered. By the movement of the crucible downward, the temperature of the bottom surface portion of the crucible is lowered, providing temperature gradient. By performing the procedure described above, the silicon melt stored in the crucible is solidified upward unidirectionally from the bottom surface of the crucible.

### RELATED ART DOCUMENT

### Patent Literature

Patent Literature 1: Japanese Unexamined Patent Application, First Publication No. H10-245216

Patent Literature 2: Japanese Unexamined Patent Application, First Publication No. 2004-058075

Patent Literature 3: Japanese Unexamined Patent Application, First Publication No. 2008-303113

### Problems to be Solved by the Invention

It has been found that there is a location that has high oxygen concentration locally at a part located in the bottom surface side of the crucible in a case where the height of the silicon melt is set high in the crucible during manufacturing a polycrystalline silicon ingot with a triangular horizontal cross-section.

Results of oxygen concentration measurement within the triangular shape at specific height positions (solidification direction positions) in a conventionally-manufactured polycrystalline silicon ingot are shown in FIGS. 6A and 6B. According to FIGS. 6A and 6B, it has been confirmed that oxygen concentration is increased locally at the central part of an outer edge side (the measurement point 3 in FIG. 6A) in the cross-section with height positions of 10 mm and 50 mm.

In the cross-section with the height position of 50 mm, oxygen concentrations at the center (the measurement point 5 in FIG. 6A) and the corner (the measurement point 3 in FIG. 6A) of the cross-section equals to or less than 5×10¹⁷ atm/cm³. However, oxygen concentration exceeds 5×10¹⁷ atm/cm³ locally (the measurement point 3 in FIG. 6A). Therefore, the slice at this height is not qualified for production of the polycrystalline silicon slice. This reduces the part of the polycrystalline silicon ingot qualified for the production, and causes a low production efficiency problem.

Recently, increasing the size of the polycrystalline silicon ingot (increasing the area of the polycrystalline silicon slice (for example, increasing a side dimension of the slice to 680 mm or more)), and raising the height of the polycrystalline silicon ingot have been attempted in order to produce the bases for solar cells from the polycrystalline silicon ingot efficiently.

However, the location with high oxygen concentration tend to be formed locally at the locations in the bottom-surface-side portion of the crucible when the polycrystalline silicon ingot is large-scaled as described above. Therefore, it is necessary to cut and remove the large portion of the polycrystalline ingot at the bottom side, making impossible to produce the polycrystalline silicon wafer efficiently.

### SUMMARY OF THE INVENTION

The present invention is made under circumstance described above, The present invention provides a polycrystalline silicon ingot manufacturing apparatus, a polycrystalline silicon ingot manufacturing method, and a polycrystalline silicon ingot, which allow a significant improvement of the production yield of the polycrystalline silicon.

The inventors of the present invention conducted intensive studies and found that unevenly distributed temperature in the crucible is the reason for the local increase of the oxygen concentration. Specifically, the oxygen concentration is increased at the locations where temperature is decreased as shown in FIGS. 6A, 6B, and 7.

Based on this finding, the inventors of the present invention got the knowledge that the local increase of oxygen concentration can be suppressed by equalizing the unevenly distributed temperature in the horizontal cross-section of the polycrystalline silicon ingot during it solidification.

The present invention is made based on the knowledge. The first aspect of the present invention is a polycrystalline silicon ingot manufacturing apparatus including: a crucible having a rectangular shape in a horizontal cross-section; an upper heater provided above the crucible; and a lower heater provided below the crucible, wherein: a silicon melt stored in the crucible is solidified from a bottom surface of the crucible upward unidirectionally; and the polycrystalline silicon ingot manufacturing apparatus further includes an auxiliary heater that heats at least a bottom-surface-side portion of a sidewall of the crucible.

During the initial stage of the unidirectional solidification, the ratio of heat dissipation from the sidewall part of the crucible is larger than that from the bottom-surface-side of the crucible. Therefore, the temperature tends to be reduced at the surface-side part (the outer edge part) of the horizontal cross-section of the polycrystalline silicon ingot.

The polycrystalline silicon ingot manufacturing apparatus, which is the first aspect of the present invention, includes the auxiliary heater that heats at least a bottom-surface-side portion of a sidewall of the crucible. Therefore, it is possible to equalize the unevenly distributed temperature in the crucible with the auxiliary heater. As a result, the local increase of oxygen concentration can be suppressed in the polycrystalline silicon ingot. Thus, there is no need to cut and remove the large portion of the polycrystalline silicon ingot at the bottom side, allowing efficient production of the polycrystalline silicon wafer.

In the polycrystalline silicon ingot manufacturing method of the first aspect of the present invention, the auxiliary heater may heat each of central parts of four sides of the ringed rectangular shape, which the crucible forms in the horizontal cross-section, and an l, which is a length of the each of the central parts along the bottom surface may be set within a range of 0.3×L≦l≦0.7×L, L being an entire length of each of the sides of the sidewall part of the crucible.

Normally, heat insulating materials are provided around the crucible. Thus, temperature decrease at the corner part in the horizontal cross section in the crucible is inhibited by the thermal effect of the heat insulating materials. On the other hand, it is regarded that in the central part of each side of the sidewall part of the horizontal cross-section of the crucible, there is less thermal effect of the heat insulating materials, causing the local temperature decrease. Therefore, by configuring the auxiliary heater to heat the each of central parts of four sides (the portion within the range of 0.3×L≦l≦0.7×L, L being an entire length of each of the sides of the sidewall part of the crucible), the unevenly distribute temperature in the crucible can be equalized reliably. Consequently, the formation of the locations with increased oxygen concentrations can be suppressed.

In the polycrystalline silicon ingot manufacturing method of the first aspect of the present invention, the auxiliary heater may be provided to face the bottom-surface-side portion of the sidewall of the crucible; and an h, which is a height of the auxiliary heater may be set within a range of 0.1×HP≦h≦0.3×HP, HP being a total height of the crucible.

When the solidification proceeds upward in the crucible, the ratio of the heat dissipation from the bottom surface side becomes large, decreasing the effect of the heat dissipation from the sidewall part. Therefore, it is necessary to equalize the unevenly distributed temperature only at the bottom-surface-side portion of the crucible. Thus, providing the auxiliary heat to face the bottom-surface-side portion of the sidewall of the crucible, and setting the height of the auxiliary heat within the range of 0.1×HP≦h≦0.3×HP, HP being a total height of the crucible, only the necessary portions in order to equalize the unevenly distributed temperature can be heated.

The second aspect of the present invention is a method of manufacturing a polycrystalline silicon ingot using the polycrystalline silicon ingot manufacturing apparatus of the first aspect of the present invention, the method including the steps of: melting in which the silicon melt is produced by melting silicon raw materials charged in the crucible; and solidifying in which the silicon melt stored in the crucible is solidified from a bottom surface of the crucible upward unidirectionally by turning off the lower heater to generate vertical temperature difference in the silicon melt stored in the crucible, wherein at least the bottom-surface-side portion of the sidewall of the crucible is heated with the auxiliary heater in the step of solidifying.

In the method of manufacturing the polycrystalline silicon ingot configured as describe above, at least the bottom-surface-side portion of the sidewall of the crucible is heated with the auxiliary heater during the solidifying step in which the silicon melt stored in the crucible is solidified from a bottom surface of the crucible upward unidirectionally. Therefore, the unevenly distributed temperature in the crucible can be equalized and the local increase of oxygen concentration in the polycrystalline silicon ingot can be suppressed. Thus, there is no need to cut and remove a large portion of the polycrystalline silicon ingot at the bottom side, making it possible to manufacture the polycrystalline silicon ingot allowing efficient production of the polycrystalline silicon wafer.

In the polycrystalline silicon ingot manufacturing method of the second aspect of the present invention, a region inside of the crucible from the bottom surface to a height X may be defined as an initial region; the sidewall of the crucible may be heated with the auxiliary heater during a height of a solid-phased silicon being within the initial region in the step of solidifying; and the height X of the initial region may be set within a range of X≦0.3×HM, HM being a height of a bath level of the silicon melt in the crucible.

The heat dissipation ratio from the sidewall part of the crucible is relatively large in the initial region (in the region where the height X is in the range of X≦0.3×HM, HM being a height of a bath level of the silicon melt in the crucible) from the bottom surface of the crucible to the height X in the step of solidifying. Therefore, there is a risk of formation of the local temperature decrease in the polycrystalline silicon ingot. In the polycrystalline silicon ingot manufacturing method of the second aspect of the present invention, the sidewall part of the crucible is heated by the auxiliary heater within the initial region. As a result, the unevenly distributed temperature in the crucible can be equalized reliably.

The third aspect of the present invention is a polycrystalline silicon ingot manufactured by the method of manufacturing a polycrystalline silicon ingot of the second aspect of the present invention, wherein: a cross-section of the polycrystalline ingot perpendicular to the solidification direction may be in a rectangular shape, each length of sides of the rectangular shape being 550 mm or longer; and oxygen concentration in the central part of the side of the rectangular shape in a horizontal cross-section at a height of 50 mm from a bottom part of the polycrystalline ingot contacting with the bottom surface of the crucible may be 5×10¹⁷ atm/cm³ or less.

In the polycrystalline silicon ingot configured as described above, the oxygen concentration in the central part of the side of the rectangular shape in a horizontal cross-section at a height of 50 mm from a bottom part of the polycrystalline ingot contacting with the bottom surface of the crucible is 5×10¹⁷ atm/cm³ or less. Therefore, the part taken from the height of 50 mm from the bottom part of the ingot can be used for production of the polycrystalline silicon wafer.

### Effect of the Invention

According to the present invention, formation of the parts with the locally high oxygen concentration can be reduced at the bottom part. Thus, the polycrystalline silicon ingot manufacturing apparatus, the polycrystalline silicon ingot manufacturing method, and the polycrystalline silicon ingot, which allow a significant improvement of the production yield of the polycrystalline silicon, can be provided.

### BRIEF DESCRIPTION OF THE DRAWINGS

FIG. 1 is a schematic view of the polycrystalline silicon ingot manufacturing apparatus of a present embodiment of the present invention.

FIG. 2 is a cross-section view of the polycrystalline silicon ingot manufacturing apparatus shown in FIG. 1 for explaining the vicinity of the crucible.

FIG. 3 is a schematic view of the polycrystalline silicon ingot of a present embodiment of the present invention.

FIG. 4A is a drawing explaining the oxygen concentration measurement points in a horizontal cross-section of the polycrystalline silicon ingot of the example of the present invention and the symbols indicating the height from the bottom of the polycrystalline silicon ingot.

FIG. 4B is a graph showing the results of the oxygen concentration measurement in the polycrystalline silicon ingot of the example of the present invention.

FIG. 5 is a drawing showing temperature distribution in the crucible (at the height position of 50 mm from the bottom) in the example of the present invention.

FIG. 6A is a drawing explaining the oxygen concentration measurement points in a horizontal cross-section of the polycrystalline silicon ingot of the comparative example and the symbols indicating the height from the bottom of the polycrystalline silicon ingot.

FIG. 6B is a graph showing the results of the oxygen concentration measurement in the polycrystalline silicon ingot of the comparative example.

FIG. 7 is a drawing showing temperature distribution in the crucible (at the height position of 50 mm from the bottom) in the comparative example.

### DETAILED DESCRIPTION OF THE INVENTION

### Best Mode for Carrying Out the Invention

The polycrystalline silicon ingot manufacturing apparatus, the polycrystalline silicon ingot manufacturing method, and the polycrystalline silicon ingot are explained as the embodiments of the present invention by reference to the attached drawings below.

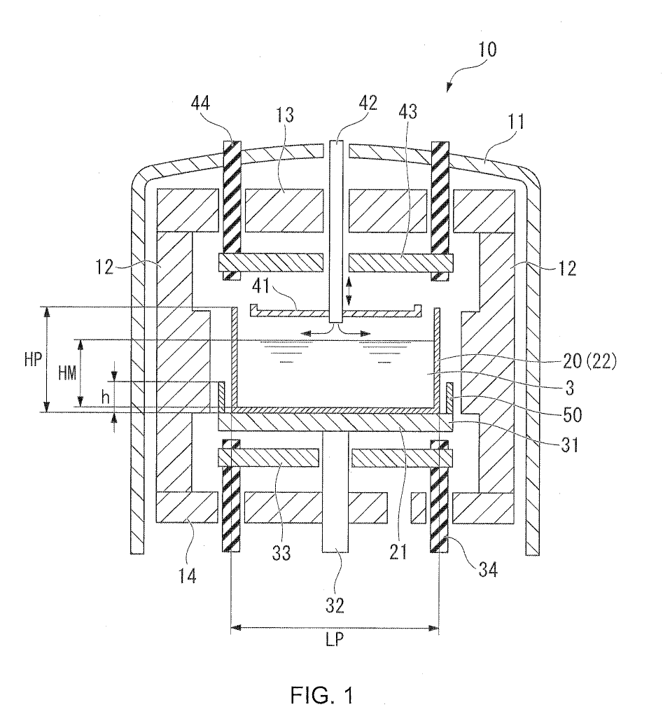

The polycrystalline silicon ingot manufacturing apparatus 10, which is one of the embodiments of the present invention, includes: a camber 11 that keeps the inside of the apparatus in an air-tight condition, a crucible 20 in which the silicon melt 3 is stored, a chill plate 31 on which the crucible 20 is placed, a lower heater 33 which is provided below the chill plate 31, an upper heater 43 which is provided above the crucible 20, and a cap portion 41 which is provided facing the opening of the crucible 20 as shown in FIG. 1. An insulating wall 12 is provided on the outer periphery side of the crucible 20. An insulating ceiling 13 is provided above the upper heater 43. An insulating floor 14 is provided below the lower heater 43. Thus, the insulating materials (the insulating wall 12, the insulating ceiling 13, and the insulating floor 14) are provided to surround the crucible 20, the upper heater 43, the lower heater 33, and the like. An auxiliary heater 50 is provided to face the sidewall part 22.

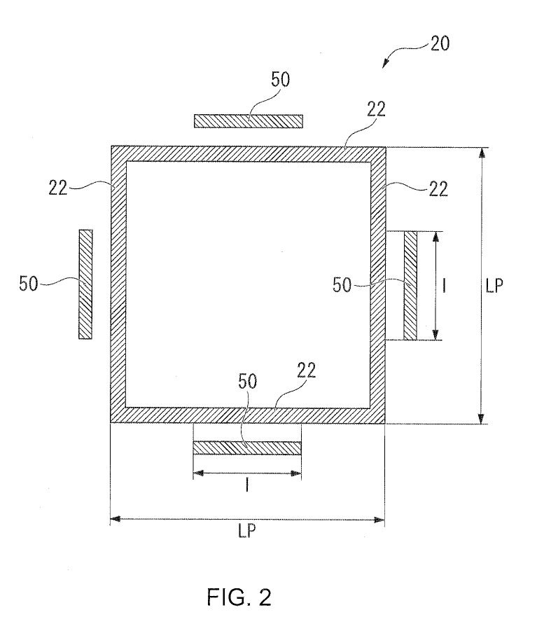

The horizontal cross-section of the crucible 20 has a rectangular shape as shown in FIG. 2. Specifically, the horizontal cross-section has a square shape in the present embodiment. The crucible 20, which is made of quartz, contains the bottom surface 21 contacting to the chill plate 31 and the sidewall parts 22 standing upward from the bottom surface 21. The horizontal cross-section of the sidewall parts 22 is in a ringed rectangular shape, The length of a side LP of the rectangular shape is 550 mm or more and 1080 mm or less. Specifically, the length LB is 680 mm in the present embodiment. The height HP of the crucible 20 (the sidewall part 22) is 500 mm or more and 700 mm or less. Specifically, the height HP is 600 mm in the present embodiment.

The upper heater 43 and the lower heater 33 are supported by the electrode rods 44, 34. The electrode rods 44, which support the upper heater 43, penetrate through the insulating ceiling 13. Parts of the electrode rods 44 are stuck out to the outside of the chamber 11. The electrode rods 34, which support the lower heater 33, penetrate through the insulating floor 14.

The chill plate 31, on which the crucible 20 is placed, is provided on the upper end of the supporting part 32 that is inserted through the lower heater 33. The chill plate 31 has a hollow structure and Ar gas is supplied in the inside of the chill plate 31 through a supply passage (not shown in the FIG. 1) provided inside of the supporting part 32.

The cap portion 41 is connected to the lower end part of the supporting axis 42, which penetrates through the upper heater 43. This cap portion 41 is made of silicon carbide or carbon, and provided to face the opening part of the crucible 20.

A gas supplying passage is provided inside of the supporting axis 42 (not shown in FIG. 1). Inert gas, such as Ar or the like, is supplied toward the silicon melt 3 stored in the crucible 20 from the opening hole provided to the end (the lower end in FIG. 1) of the supporting axis 42.

The supporting axis 42 and the cap portion 41 can be moved upward and downward to adjust the distance to the bath level of the silicon melt 3 stored in the crucible 20.

To the polycrystalline silicon ingot manufacturing apparatus 10, the auxiliary heater 50, which heats at least a part of the bottom surface 21 side of the sidewall part 22 of the crucible 20, is provided in addition to the upper heater 43 and the lower heater 33. In the present embodiment, the auxiliary heater 50 is provided to face the sidewall part 22 of the crucible 20 as shown in FIG. 1. The height h of the auxiliary heater 50 is set in a range of 0.1×HP≦h≦0.3×HP, HP being a total height of the crucible 20. More preferably, the height h is set within the range of 0.20×HP≦h≦0.25×HP.

Also, the auxiliary heater 50 is provided to face central part of the side of the rectangular shape formed by the sidewall parts 22 of the crucible 20 in a horizontal cross-section. The central part means the part to which the auxiliary heater 50, which faces to the side of the rectangular shape formed by the sidewall parts 22 of the crucible, is projected on the facing side. The length l of the central part (in other words, the width 1 of the auxiliary heater 50) is set within the range of 0.3×LP≦l≦0.7×LP, LP being an entire length of each of the sides of the sidewall part 22 of the crucible 20. More preferably, the length l is set within the range of 0.4×LP≦l≦0.5×LP.

The auxiliary heater 50 is a radiant heater and locally heats the part that the auxiliary heater 50 is provide to face among the sidewall part 22 of the crucible 20. The output power of the auxiliary heater 50 is relatively low, such as 10 to 50% of the output power of the lower heater 33.

Next, the polycrystalline silicon ingot manufacturing method, which is an embodiment of the present invention, is explained. In this embodiment, the polycrystalline silicon ingot 1 is manufactured with the polycrystalline silicon ingot manufacturing apparatus 10.

First, silicon raw materials are charged in the crucible 20 (Silicon Raw Material Charging Step S01). Here, the blocks of silicon raw materials called “chunks”, which are obtained by fracturing the 11 N (99.999999999) high purity grade silicon, are used as the silicon raw materials. Grain diameter of the block silicon raw materials is 30 mm to 100 mm, for example.

Next, the silicon raw materials charged in the crucible 20 are heated by turning on the upper and lower heaters to generate the silicon melt 3 (Melting Step S02). Here, the heating of the silicon raw materials can be accelerated by turning on the auxiliary heater 50. In this step, the bath level of the silicon melt 3 in the crucible 20 is set lower than the upper end of the sidewall part 22 of the crucible 20.

Next, the silicon melt 3 in the crucible 20 is solidified upward unidirectionally from the bottom part of the crucible 20 (Solidifying Step S03). First, the lower heater 33 is turned off, and Ar gas is supplied to the inside of the chill plate 31 through the supply passage. Because of these, the bottom part of the crucible 20 is cooled. In this step, a temperature gradient is generated upward from the bottom surface 21 in the crucible 20 by keeping the upper heater 43 turned on. With the temperature gradient, the silicon melt 3 is solidified upward unidirectionally. Further, the output power of the upper heater 43 is gradually reduced. By following the process above, the silicon melt 3 in the crucible 20 is solidified upward, generating the polycrystalline silicon ingot 1.

In the solidifying step S03, the part of the sidewall part 22 of the crucible 20 is heated with the auxiliary heater 50, during the height of the solid phase of the silicon in the crucible 20 being within the initial region where the height of the solid phase is equals to or less than the height X from the bottom surface 21 of the crucible 20. The height X of the initial region is set within the range of X≦0.3×HM, HM being the height of a bath level of the silicon melt 3 in the crucible 20, In other words, the auxiliary heater 50 is turned on within the initial region in the solidifying step S03 and turned off when the height of the solid phase exceeds the initial region, A preferable height X of the initial region is set within the range of X≦0.1×HM.

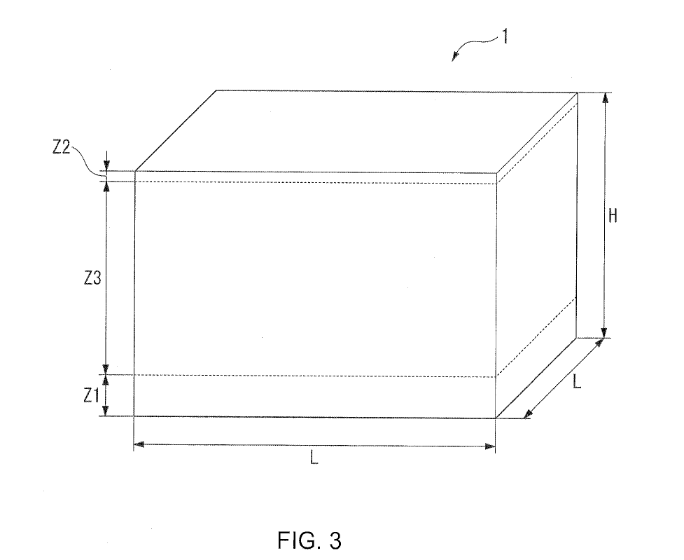

As described above, the polycrystalline silicon ingot 1 shown in FIG. 3 is casted by the unidirectional solidifying method. The polycrystalline silicon ingot 1 can be used as the material of the polycrystalline silicon wafer utilized for the base of the solar cells.

The polycrystalline silicon ingot 1 is in a quadrangular prism shape as shown in FIG. 3. The height H of the polycrystalline silicon ingot 1 is 200 mm or more and 350 mm or less. Specifically, the height H of the polycrystalline silicon ingot 1 is 300 mm in the present embodiment. Also, the horizontal cross-section of the polycrystalline silicon ingot 1 is in a rectangular and square shape in this embodiment, The length L of a side of the square is 550 mm or more and 1080 mm or less. Specifically, the length L is 680 mm in the present embodiment.

At the bottom side part Z1 of the polycrystalline silicon ingot 1, oxygen concentration is high. At the top side part Z2 of the polycrystalline silicon ingot 1, the concentration of impurities is high. Thus, both the bottom side part Z1 and the top side part Z2 are cut and removed, and only the product part Z3 is used for production of the polycrystalline silicon wafer.

The highest oxygen concentration in the horizontal cross-section at the height of 50 mm from the bottom part is 5×10¹⁷ atm/cm³ or less in the polycrystalline silicon ingot 1. In other words, the oxygen concentration in the central part of the side of the rectangular shape in a horizontal cross-section is 5×10¹⁷ atm/cm³ or less. The oxygen concentration is measured by taking out a test sample having a dimension of 5 mm×5 mm×5 mm from the horizontal cross-section and measuring the oxygen concentration with a Fourier Transform Infrared Spectroscopy (FI-IR) in the present embodiment. For the Fourier Transform Infrared Spectroscopy, a model FTIR4100 manufactured by JASCO Corporation is used.

The polycrystalline silicon ingot manufacturing apparatus 10, the method of manufacturing the polycrystalline silicon ingot 1, and the polycrystalline silicon ingot 1, are configured as described above. According to the present embodiments, generation of the local temperature decrease, which occurs because of the heat dissipation from the sidewall parts 22 of the crucible 20, can be suppressed, since the auxiliary heater 50 is provided to face the part located in the bottom surface 21 side among the sidewall parts 22 of the crucible 20. Therefore, the uneven temperature distribution can be equalized in the horizontal cross-section at the bottom surface 21 side of the crucible 20, suppressing the local increase of the oxygen concentration in the polycrystalline silicon ingot 1.

Only less thermal effect is provided by the insulating wall 12 at the central part of the each side of the ringed rectangular shape in the horizontal cross-section formed by the sidewall parts 22. Therefore, there is a tendency that local temperature decrease occurs at the location. However, the uneven temperature distribution can be equalized since the auxiliary heater 50 heats the above-mentioned central part of the sidewall parts 22 (the part located within the range of 0.3×L≦l≦0.7×L, L being an entire length of each of the sides of the sidewall part of the crucible) in the present embodiment.

In addition, the heat dissipation from the sidewall parts 22 in the bottom surface 21 side part can be suppressed, since the auxiliary heater 50 is provided to face at least a part of the bottom surface 21 side of the crucible 20 among the sidewall parts 22 of the crucible 20, and the height h of the auxiliary heater 50 is set to a range of h≦0.1×HP, HP being a total height of the crucible 20. In addition, progress of the unidirectional solidification can be facilitated without interfering the vertical temperature gradient at the upper part of the crucible 20, since the height h of the auxiliary heater 50 is set to a range of h≦0.3×HP.

Furthermore, an embodiment of the present invention includes: the raw material charging step S01, in which the silicon raw materials are charged in the crucible 20, the melting step S02, in which the silicon melt 3 is generated by melting the silicon raw materials charged in the crucible 20, and the solidification step S03, in which the silicon melt 3 stored in the crucible 20 is solidified upward unidirectionally from the bottom surface 21 side of the crucible 20. Also, the embodiment is provided with a configuration in which the sidewall parts 22 of the crucible 20 is heated in the initial region in the solidification step S03. Therefore, the uneven temperature distribution is equalized in the horizontal cross-section in the bottom surface 21 side of the crucible 20, suppressing the local increase of oxygen concentration in the polycrystalline silicon ingot 1.

As explained above, according to the present embodiment, the polycrystalline silicon ingot manufacturing apparatus 10, the polycrystalline silicon ingot manufacturing method, and the polycrystalline silicon ingot 1, which allow a significant improvement of the production yield of the polycrystalline silicon, can be provided by reducing part having locally increased oxygen concentration at the bottom part.

The polycrystalline silicon ingot manufacturing apparatus, the polycrystalline silicon ingot manufacturing method, and the polycrystalline silicon ingot, are explained above as the embodiments of the present invention. However, the present invention is not particularly limited by the description of the present embodiments, and the configurations of the aspects of the present invention can be omitted, substituted, or modified appropriately.

For example, the size of the polycrystalline silicon ingot or the like is not particularly limited by the description of the embodiments, and can be changed appropriately.

In the description of the embodiments, the auxiliary heater is provided to face the sidewall part of the crucible. However, the aspect of the present invention is not limited by this configuration. Thus, an auxiliary heater can be provided around the lower heater. In this configuration, the part of the sidewall part of the crucible is heated from the lower part of the chill plate to equalize the uneven temperature distribution.

In the description of the embodiments, the auxiliary heater is provided to face the central part of the side of the ringed rectangular shape in the horizontal cross-section formed by the sidewall parts. However, the aspect of the present invention is not limited by the description. Thus, an auxiliary heater can be provided in such a way that it face all of the sides (in other words, the auxiliary enclose the crucible in the cross-section).

### EXAMPLES

Experimental results for confirming the effect of the present invention is shown below. A polycrystalline silicon ingot in a quadrangular prism shape having a dimension of 680 mm×680 mm×300 mm (height) was manufactured with the polycrystalline silicon ingot manufacturing apparatus explained as a present embodiment. In this Example, the width 1 of the auxiliary heater was set to 400 mm, and the height h of the auxiliary heater was set to 100 mm.

As a comparative example, an unidirectional solidification was performed without using the auxiliary heater. The solidification rate was 5 mm/h.

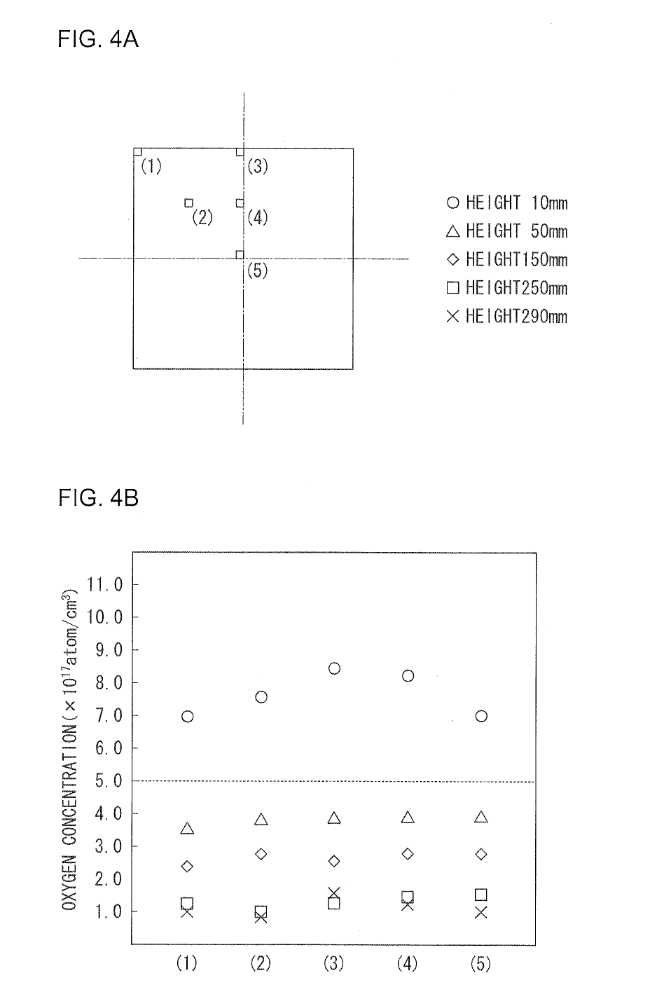

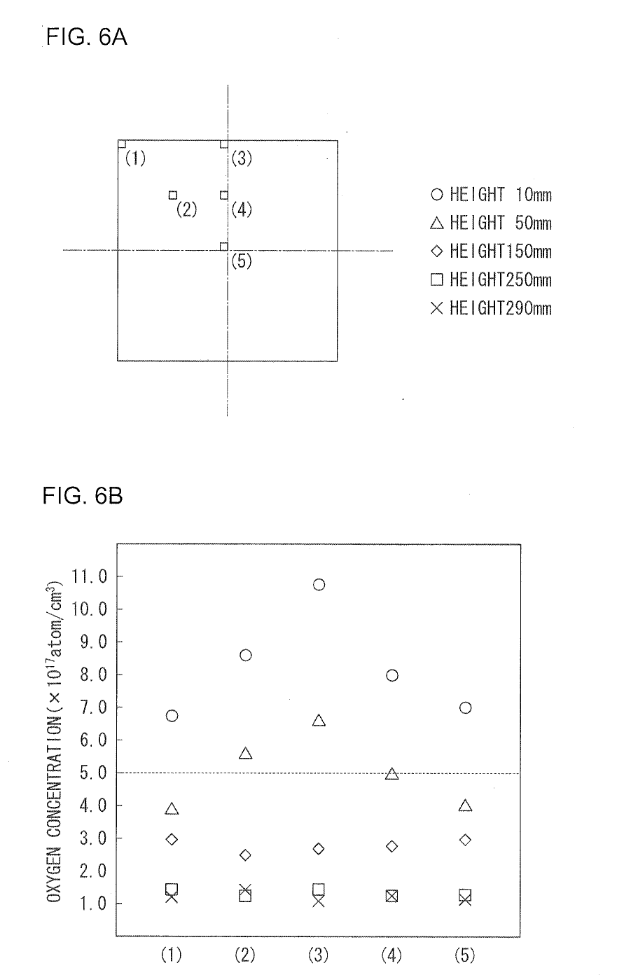

Test samples having the dimension of 5 mm×5 mm×5 mm were taken from each 5 locations shown in the FIGS. 4A and 6A at the heights of 10 mm, 50 mm, 150 mm, 250 mm, and 290 mm of the both polycrystalline silicon ingots of the Comparative Example and the Example of the present invention. The oxygen concentrations in the test samples were measured with a Fourier Transform Infrared Spectroscopy (FI-IR) the in the present embodiment. For the Fourier Transform Infrared Spectroscopy. The results obtained from the ingot of the Example of the present invention is shown in FIG. 4B. The results obtained from the ingot of the Comparative Example is shown in FIG. 6B.

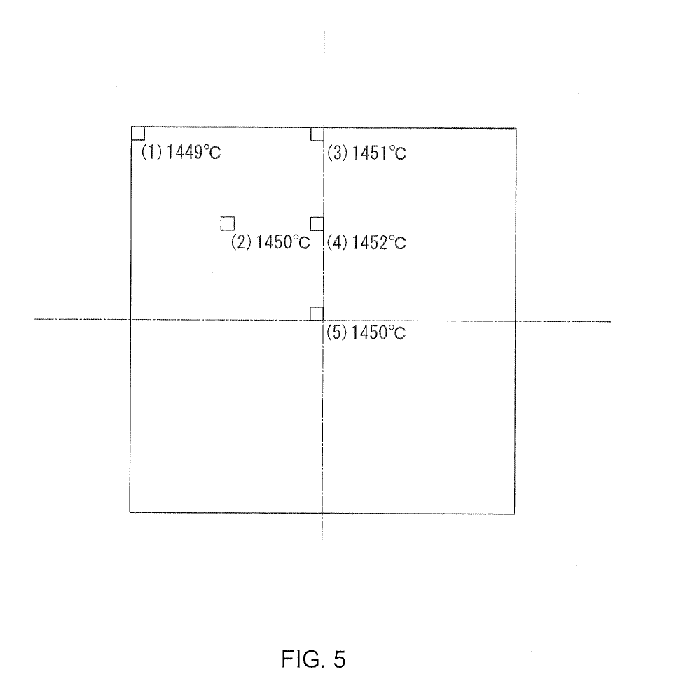

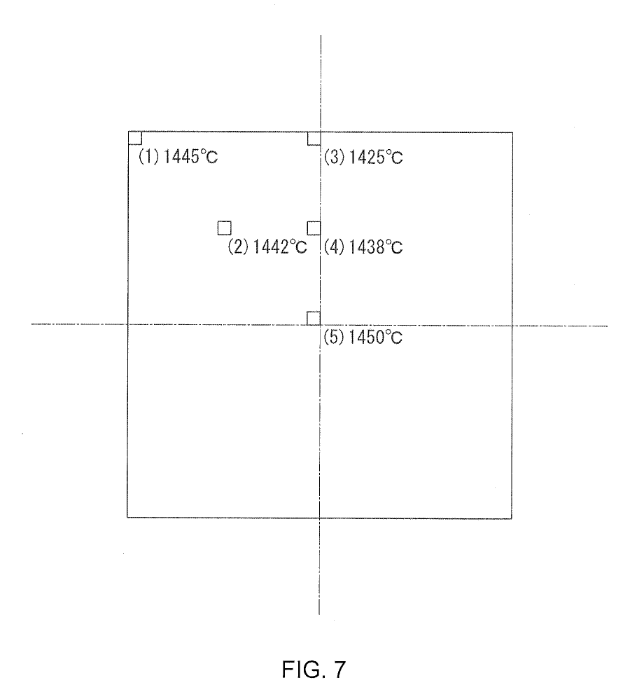

Also, the temperature of the silicon melts at the height from the bottom surface of the crucible in both the Comparative Example and the Example of the present invention were measured. The temperature distribution diagrams at the height of 50 mm from the bottom surface of the crucible ware obtained in the condition where the output powers of the lower and upper heaters (also and the auxiliary heater in the Example of the present invention) were controlled so as to retain the central part of the crucible to be 1450° C. The temperature distribution diagram obtained in the Example of the present invention is shown in FIG. 5. The temperature distribution diagram obtained in the Comparative Example is shown in FIG. 7.

As shown in FIGS. 4B and 6B, the oxygen concentrations at the height of 10 mm from the bottom surface exceeded 5×10¹⁷ atm/cm³ in both the Example of the present invention and the Comparative Example.

Also, at the heights of 150 mm, 250 mm, and 290 mm, the oxygen concentrations at any positions were 5×10¹⁷ atm/cm³ or less.

In the Comparative Example, at the height of 50 mm from the bottom surface, the oxygen concentrations exceeded 5×10¹⁷ atm/cm³ at the locations excluding the corner part and the central part in the horizontal cross-section.

Contrary to that, in the Example of the present invention, at the height of 50 mm from the bottom surface, the oxygen concentrations were 5×10¹⁷ atm/cm³ or less in any locations in the horizontal cross-section.

In the temperature distribution diagrams of the Comparative Example, there was a part having a locally decreased temperature in the central part of the side of the rectangular shape in the horizontal cross-section as shown in FIG. 7.

Contrary to that, in the temperature distribution diagram of the Example of the present invention, there was no part having a locally decreased temperature in the central part of the side of the rectangular shape in the horizontal cross-section as shown in FIG. 5. The finding confirms that the temperature distribution was equalized in the horizontal cross-section in the Example of the present invention.

Here, the production yield R of the polycrystalline ingot was calculated when only the part of the polycrystalline silicon ingot having the oxygen concentration of 5×10⁷ atm/cm³ or less is used for the production. In this calculation, the production yield was calculated regarding that the top part of the ingot from the top to 10 mm from the top was cut and removed due to its high content of the impurities.

In the Conventional Example, there were locations having the oxygen concentrations exceeding 5×10¹⁷ atm/cm³ locally at the height position of 50 mm from the bottom surface as shown in FIG. 6B. Therefore, the polycrystalline silicon ingot including the region could not be used for the production. Because of this, the cutting margin at the bottom side was set to 150 mm. In this case, the production yield R was 46.7%, calculated by the formula R=(300 mm−(150 mm+10 mm))/300 mm.

Contrary to that, in the Example of the present invention, the oxygen concentrations were 5×10¹⁷ atm/cm³ or less at any measurement points at the height position of 50 mm from the bottom surface as shown in FIG. 4B. Therefore, it was possible to utilize the polycrystalline silicon ingot including this region. In the Example of the present invention, the cutting margin at the bottom side was set to 50 mm. In this case, the production yield R was 80.0%, calculated the formula

R=(300 mm−(50 mm+10 mm))/300 mm.

As explained above, it was confirmed that the production yield of the polycrystalline silicon as the product could be significantly improved according to the present invention.

### INDUSTRIAL APPLICABILITY

According to the present invention, the polycrystalline silicon ingot manufacturing apparatus, the polycrystalline silicon ingot manufacturing method, and the polycrystalline silicon ingot, which allow a significant improvement of the production yield of the polycrystalline silicon by reducing the locations having locally increased oxygen concentrations at the bottom part, can be provided.

### BRIEF DESCRIPTION OF THE REFERENCES SYMBOLS

1: Polycrystalline silicon ingot
3: Silicon melt
10: Polycrystalline silicon ingot manufacturing apparatus
20: Crucible
21: Bottom surface
22: Sidewall part
33: Lower heater
43: Upper heater
50: Auxiliary heater

1. A polycrystalline silicon ingot manufacturing apparatus comprising:
a crucible having a rectangular shape in a horizontal cross-section;
an upper heater provided above the crucible; and
a lower heater provided below the crucible, wherein:
a silicon melt stored in the crucible is solidified from a bottom surface of the crucible upward unidirectionally; and
the polycrystalline silicon ingot manufacturing apparatus further comprises an auxiliary heater that heats at least a bottom-surface-side portion of a sidewall of the crucible.

2. The polycrystalline silicon ingot manufacturing apparatus according to claim 1, wherein the auxiliary heater heats each of central parts of four sides of a ringed rectangular shape, which the crucible forms in the horizontal cross-section, and
an l, which is a length of each of the central parts along the bottom surface is set within a range of 0.3×L≦l≦0.7×L, L being an entire length of each of the sides of the sidewall part of the crucible.

3. The polycrystalline silicon ingot manufacturing apparatus according to claim 1, wherein
the auxiliary heater is provided to face the bottom-surface-side portion of the sidewall of the crucible; and
an h, which is a height of the auxiliary heater is set within a range of 0.1×HP≦h≦0.3×HP, HP being a total height of the crucible.

4. A method of manufacturing a polycrystalline silicon ingot using the polycrystalline silicon ingot manufacturing apparatus according to claim 1, the method comprising the steps of:
melting silicon raw materials charged in the crucible to produce the silicon melt; and
solidifying the silicon melt stored in the crucible from a bottom surface of the crucible upward unidirectionally by turning off the lower heater to generate vertical temperature difference in the silicon melt stored in the crucible, wherein
at least the bottom-surface-side portion of the sidewall of the crucible is heated with the auxiliary heater in the step of solidifying.

5. The method of manufacturing a polycrystalline silicon ingot according to claim 4, wherein
a region inside of the crucible from the bottom surface to a height X is defined as an initial region;
the sidewall of the crucible is heated with the auxiliary heater during a height of a solid-phased silicon being within the initial region in the step of solidifying; and
the height X of the initial region is set within a range of X≦0.3×HM, HM being a height of a bath level of the silicon melt in the crucible.

6. A polycrystalline silicon ingot manufactured by the method of manufacturing a polycrystalline silicon ingot according to claim 4, wherein:
a cross-section of the polycrystalline ingot perpendicular to the solidification direction is in a rectangular shape, each length of sides of the rectangular shape being 550 mm or longer; and
an oxygen concentration in the central part of the side of the rectangular shape in a horizontal cross-section at a height of 50 mm from a bottom part of the polycrystalline ingot contacting with the bottom surface of the crucible is 5×10¹⁷ atm/cm³ or less.

7. The polycrystalline silicon ingot manufacturing apparatus according to claim 2, wherein
the auxiliary heater is provided to face the bottom-surface-side portion of the sidewall of the crucible; and
an h, which is a height of the auxiliary heater is set within a range of 0.1×HP≦h≦0.3×HP, HP being a total height of the crucible.

8. A method of manufacturing a polycrystalline silicon ingot using the polycrystalline silicon ingot manufacturing apparatus according to claim 2, the method comprising the steps of:
melting silicon raw materials charged in the crucible to produce the silicon melt; and
solidifying the silicon melt stored in the crucible from a bottom surface of the crucible upward unidirectionally by turning off the lower heater to generate vertical temperature difference in the silicon melt stored in the crucible, wherein
at least the bottom-surface-side portion of the sidewall of the crucible is heated with the auxiliary heater in the step of solidifying.

9. A polycrystalline silicon ingot manufactured by the method of manufacturing a polycrystalline silicon ingot according to claim 5, wherein:
a cross-section of the polycrystalline ingot perpendicular to the solidification direction is in a rectangular shape, each length of sides of the rectangular shape being 550 mm or longer; and
an oxygen concentration in the central part of the side of the rectangular shape in a horizontal cross-section at a height of 50 mm from a bottom part of the polycrystalline ingot contacting with the bottom surface of the crucible is 5×10¹⁷ atm/cm³ or less.
